(19) United States
(12) Patent Application Publication
(10) Pub. No.: US 2026/0026155 A1
(43) Pub. Date: Jan. 22, 2026

(54) DISPLAY DEVICE

(71) Applicant: LG Display Co., Ltd., Seoul (KR)

(72) Inventors: JunYoung JO, Paju-si (KR); TaeYoon KIM, Seoul (KR); BungGoo KIM, Paju-si (KR); HyoungHo AHN, Paju-si (KR); HeeWon LEE, Paju-si (KR); HyeSun JUNG, Seoul (KR)

(73) Assignee: LG Display Co., Ltd., Seoul (KR)

(21) Appl. No.: 19/221,129

(22) Filed: May 28, 2025

(30) Foreign Application Priority Data
Jul. 17, 2024 (KR) 10-2024-0094417

(51) Int. Cl. H10H 29/39; H10H 29/34; H10H 29/37

(52) U.S. Cl. CPC H10H 29/39; H10H 29/34; H10H 29/37

(57) ABSTRACT

According to an aspect of the present disclosure, a display device includes a substrate in which a plurality of first pixels and a plurality of second pixels are defined. One or more pixel driving circuits are disposed on the substrate, and a plurality of micro LEDs is disposed in the plurality of first pixels and the plurality of second pixels and electrically connected to the pixel driving circuit. Each of the plurality of first pixels includes one pair of first sub pixels and one pair of second sub pixels and each of the plurality of second pixels includes one pair of third sub pixels and one pair of fourth sub pixels. By providing first and second pixels with different sub pixel combinations, the display device implements a pentile structure that enhances resolution while maintaining compact pixel arrangements.

### CROSS-REFERENCE TO RELATED APPLICATIONS

This application claims the priority benefit of Korean Patent Application No. 10-2024-0094417 filed on Jul. 17, 2024, in the Korean Intellectual Property Office, the disclosure of which is incorporated herein by reference.

### BACKGROUND

### Technical Field

The present disclosure relates to a device and particularly to, for example, without limitation, a display device.

### Description of the Related Art

Display devices are being applied to various electronic devices, such as TVs, mobile phones, notebooks, and tablets.

As display devices, there are an organic light emitting display (OLED) which is a self-emitting device and a liquid crystal display (LCD) which requires a separate light source.

In recent years, a display device including a micro light emitting diode (mLED or μLED) as a light emitting element is attracting attention as a next generation display device. The micro LED is formed of an inorganic material, rather than an organic material so that lighting speed is faster, a luminous efficiency is excellent, and an image with a higher luminance is displayed, as compared with the liquid crystal display or the organic light emitting display.

### BRIEF SUMMARY

The disclosed display device integrates multiple sub-pixels into a single pixel driving circuit, reducing circuit complexity and enabling lower power consumption. It adopts an RG BG pentile structure, where alternating pixels include different sub-pixel combinations (e.g., red/green and blue/green), allowing for higher pixel density and resolution with improved efficiency. To enhance manufacturing yield and reliability, each sub-pixel includes both a main and a redundancy micro-LED, enabling fallback in case of transfer defects.

Additionally, the display includes stress-relieving link lines formed from ductile materials and patterned geometries in bendable areas to improve mechanical reliability. The device employs stacked organic protection layers, selectively removed in flexible regions, and features optimized electrode configurations—shared signal lines with time-division driving, and transparent second electrodes for high optical performance and simplified micro-LED alignment. These features collectively support high-resolution, low-power, and mechanically robust display operation.

For example, various embodiments of the present disclosure provide a display device with a simplified structure of a plurality of pixel circuits.

Various embodiments of the present disclosure provide a display device in which a plurality of pixel circuits is integrated in one pixel driving circuit to be driven at a low power and the power consumption is reduced.

Various embodiments of the present disclosure provide a display device with an RG BG pentile pixel structure.

Various embodiments of the present disclosure provide a display device which has a high PPI to display a high resolution image.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate in which a plurality of first pixels and a plurality of second pixels are defined; one or more pixel driving circuits disposed on the substrate; and a plurality of micro LEDs which is disposed in the plurality of first pixels and the plurality of second pixels and is electrically connected to the pixel driving circuit. Each of the plurality of first pixels includes one pair of first sub pixels and one pair of second sub pixels and each of the plurality of second pixels includes one pair of third sub pixels and one pair of fourth sub pixels. Accordingly, a first pixel and a second pixel having sub pixels with different combinations are provided to implement a display device with a pentile structure.

According to another aspect of the present disclosure, a display device includes a substrate in which a plurality of first pixels and a plurality of second pixels are defined; one or more pixel driving circuits disposed on the substrate; a plurality of main micro LEDs which is disposed in the plurality of first pixels and the plurality of second pixels and is electrically connected to the pixel driving circuit; and a plurality of redundancy micro LEDs which is disposed in the plurality of first pixels and the plurality of second pixels and is electrically connected to the pixel driving circuit. Each of the plurality of first pixels includes one pair of red sub pixels and one pair of green sub pixels and each of the plurality of second pixels includes one pair of blue sub pixels and one pair of green sub pixels. Accordingly, the plurality of pixels includes a main micro LED and a redundancy micro LED to prepare for a defect of the main micro LED.

Other detailed matters of the exemplary embodiments are included in the detailed description and the drawings.

According to the present disclosure, the plurality of pixel circuits is integrated in one pixel driving circuit to be efficiently driven at a lower power.

According to the present disclosure, a plurality of pixels is configured in an RG BG pentile structure to reduce a size of each of the plurality of pixels.

According to the present disclosure, a size of each of the plurality of pixels is reduced to form more pixels to display a high resolution image.

The effects according to the present disclosure are not limited to the contents exemplified above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a perspective view illustrating a display device according to an exemplary embodiment of the present disclosure;

FIG. 2 is a plan view of a display device according to an exemplary embodiment of the present disclosure;

FIG. 3 is an enlarged view of a display device according to an exemplary embodiment of the present disclosure;

FIG. 4 is a view illustrating a circuit structure according to an exemplary embodiment of the present disclosure;

FIGS. 5 and 6 are schematic diagrams of a display device according to an exemplary embodiment of the present disclosure;

FIGS. 7 to 9 are plan views of a display device according to an exemplary embodiment of the present disclosure;

FIG. 10 is a cross-sectional view of a display device according to an exemplary embodiment of the present disclosure;

FIG. 11 is a cross-sectional view of a display device according to an exemplary embodiment of the present disclosure; and

FIGS. 12 to 15 are views illustrating devices to which a display device according to exemplary embodiments of the present disclosure is applied.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

Any implementation described herein as an “example” is not necessarily to be construed as preferred or advantageous over other implementations.

When the position relation between two parts is described using the terms such as “on,” “above,” “below,” and “next,” one or more parts may be positioned between the two parts unless the terms are used with the term “immediately” or “directly.”

When the temporal relationship is described using the terms such as “after,” “following,” “next to,” and “before,” there may also be cases where they are not consecutive, unless “immediately” or “directly” is used.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

In describing components of this specification, terms such as first, second, A, B, (a), or (b) may be used. These terms are only intended to distinguish the components from other components, and the nature, order, sequence, or number of components are not limited by the terms.

When a component is described as being “connected,” “coupled,” “attached” or “attached” to another component, it should be understood that the component may be directly connected, coupled, connected, or attached to the other component, but that other components may be interposed between each component that may be indirectly connected, coupled, connected, or attached without any specific explicit description.

When a component or layer is described as being “contacted” or “overlapped,” it should be understood that the component or layer may directly contact or overlap the other component or layer, but that other components may be interposed between each component that may be indirectly contacted or overlapped without any specific explicit description.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

“At least one” should be understood to include any combination of one or more of the associated components. For example, “at least one of the first, second, and third components” can be interpreted to include not only the first, second, or third components, but also any combination of two or more of the first, second, and third components.

“First direction,” “Second direction,” “Third direction,” “X-axis direction,” “Y-axis direction,” and “Z-axis direction” should not be interpreted as a geometric relationship in which the relationship between each other is perpendicular, but can mean a wider directionality within the range in which the configuration of the present specification can function functionally.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Each feature of the various embodiments of the present specification can be partially or wholly combined or combined with each other, and various technical connections and operations are possible, and each embodiment can be implemented independently of each other or can be implemented together in a related relationship.

Hereinafter, an exemplary embodiment of the present disclosure will be described in detail with reference to the drawings.

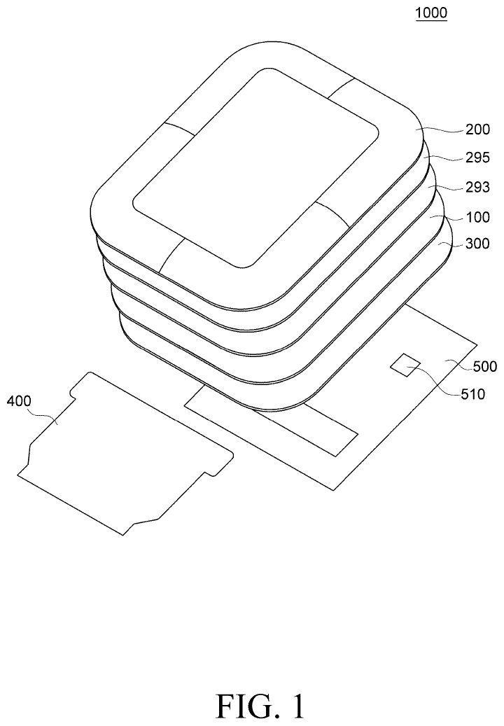

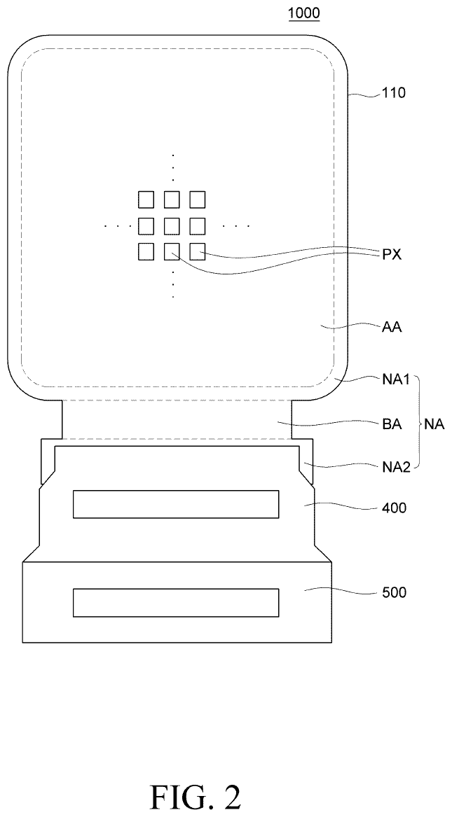

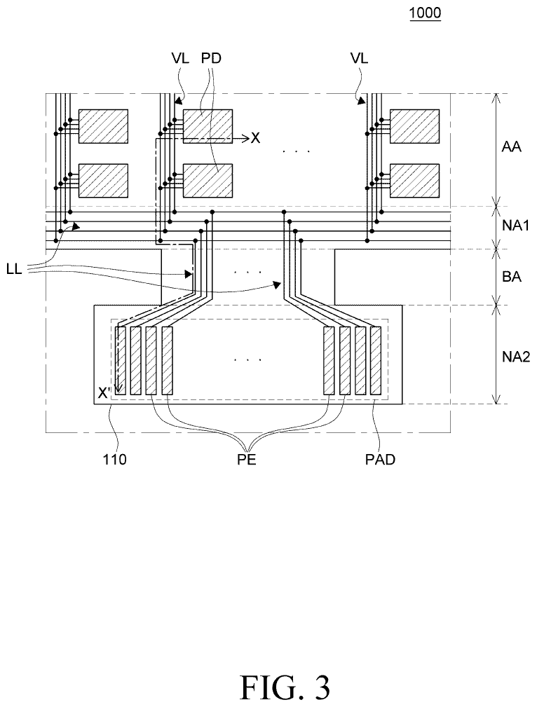

FIG. 1 is a perspective view illustrating a display device according to an exemplary embodiment of the present disclosure. FIG. 2 is a plan view of a display device according to an exemplary embodiment of the present disclosure. FIG. 3 is an enlarged view of a display device according to an exemplary embodiment of the present disclosure.

Referring to FIGS. 1 to 3, a display device 1000 according to an exemplary embodiment of the present disclosure may include a display panel 100, a polarization layer 293, an adhesive layer 295, a cover member 200, a support substrate 300, a flexible circuit board 400, and a printed circuit board 500.

For example, the display panel 100 of the display device 1000 may include a substrate 110. The substrate 110 may be a member which supports other components of the display device 1000. The substrate 110 is formed of an insulating material. For example, the substrate 110 may be formed of glass or resin. Further, the substrate 110 may also be formed of a material having a flexibility. For example, the substrate 110 may be formed of a plastic material having flexibility, such as polyimide (PI). However, the exemplary embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. However, the active area AA and the non-active area NA are not mentioned to be limited to the substrate 110, but mentioned for the entire display device 1000.

The active area AA is an area where images are displayed. The active area AA includes a plurality of pixels PX. Each of the plurality of pixels PX may be configured by a plurality of sub pixels. A plurality of light emitting diodes may be disposed in each of the plurality of sub pixels. The plurality of light emitting diodes may be configured in different manners depending on the type of the display device 1000. For example, when the display device 1000 is an inorganic light emitting display device, the light emitting diode may be a light emitting diode (LED), a micro light emitting diode (micro LED), or a mini light emitting diode (mini LED), but the exemplary embodiments of the present disclosure are not limited thereto. Hereinafter, the description will be made by assuming that the light emitting diode of the display device 1000 according to the exemplary embodiment of the present disclosure is a micro LED, but the exemplary embodiments of the present disclosure are not limited thereto.

The non-active area NA is an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied may be disposed. For example, the control signal may include various timing signals including a clock signal, an input data enable signal, and synchronization signals, but the exemplary embodiments of the present disclosure are not limited thereto. The control signal may be received through the pad unit PAD. For example, in the non-active area NA, link lines LL may be disposed to transmit signals. For example, driving components, such as the flexible circuit board 400 and the printed circuit board 500, may be connected to the pad unit PAD.

According to the present specification, the non-active area NA may include a first non-active area NA1, a bending area BA, and a second non-active area NA2. For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD may be disposed therein. For example, the bending area BA is in a bent state and the other areas of the substrate 110 excluding the bending area BA may be in a flat state. In this case, as the bending area BA is bent, the second non-active area NA2 may be located on a rear surface of the active area AA, but the exemplary embodiments of the present disclosure are not limited thereto.

The active area AA of the substrate 110 or the display device 1000 may be configured with various shapes depending on a design of the display device 1000. For example, the active area may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drives manufactured using a metal-oxide-silicon field effect transistor (MOSFET) manufacturing process on a semiconductor substrate, but the exemplary embodiments of the present disclosure are not limited thereto. The driving driver includes a plurality of pixel driving circuits PD and may drive a plurality of sub pixels.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the exemplary embodiments of the present disclosure are not limited thereto. One side of the flexible circuit board 400 is attached to the display panel 100 and the other side is attached to the printed circuit board 500, but the exemplary embodiments of the present disclosure are not limited thereto. The flexible circuit board 400 may be a flexible film, but the exemplary embodiments of the present disclosure are not limited thereto.

A pad unit PAD including a plurality of pad electrodes PE may be disposed in the second non-active area NA2. In the pad unit PAD, a driving component including one or more flexible circuit board (or a flexible film) 400 and the printed circuit board 500 may be attached or bonded. The plurality of pad electrodes PE of the pad unit PAD is electrically connected to one or more flexible circuit boards (or flexible films) 400 and may transmit various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) 400 may be attached or bonded onto the plurality of pad electrodes PE through a conductive adhesive layer, but the exemplary embodiments of the present disclosure are not limited thereto.

The printed circuit board 500 may be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed. For example, the printed circuit board 500 may include a power management integrated circuit (PMIC), but the exemplary embodiments of the present disclosure are not limited thereto.

The printed circuit board 500 may include at least one hole 510, but the exemplary embodiments of the present disclosure are not limited thereto. An internal component which senses ambient light or temperature to be supplied to a plurality of sensors may be disposed in an area corresponding to at least one hole 510. For example, the internal component may include an ambient light sensor (ALS) or a temperature sensor, but the exemplary embodiments of the present disclosure are not limited thereto. For example, the hole 510 may be a transmission hole, but the exemplary embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering the display panel 100.

A cover member 200 may be disposed on the polarization layer 293. The cover member 200 may be a member for protecting the display panel 100. An adhesive layer 295 may be disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

A support substrate 300 may be disposed between the display panel 100 and the printed circuit board 500. The support substrate 300 may reinforce a rigidity of the display panel 100. The support substrate 300 may be a back plate, but the exemplary embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) 400 and the printed circuit board 500 through the driving line VL of the active area AA and the link line LL of the non-active area NA to be driven.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, a part of the plurality of link lines LL is bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the exemplary embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the exemplary embodiments of the present disclosure are not limited thereto. Accordingly, in order to minimize or reduce a stress concentrated on the plurality of link lines LL and a crack caused thereby, a shape of the plurality of link lines LL may be various shapes including the above-mentioned shapes, but the exemplary embodiments of the present disclosure are not limited thereto.

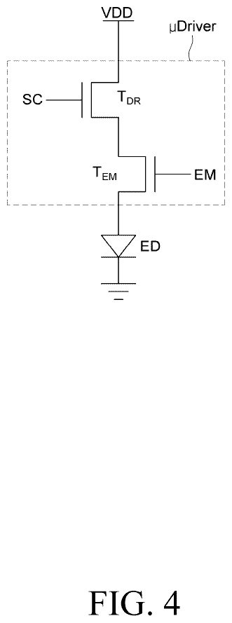

FIG. 4 is a view illustrating a circuit structure according to an exemplary embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LED (ED) may be simultaneously connected to one micro driver (μDriver).

One micro driver (μDriver) may include a driving transistor TDR and an emission transistor TEM, but the exemplary embodiments of the present disclosure are not limited thereto.

For example, a high potential power voltage VDD is applied to a first electrode of the driving transistor TDR and a first electrode of the emission transistor TEM is connected to a second electrode, and a scan signal SC may be applied to a gate electrode. The scan signal SC applied to the gate electrode of the driving transistor TDR is a direct current (DC) power and a fixed reference voltage may be applied in every frame, but the exemplary embodiments of the present disclosure are not limited thereto.

The second electrode of the driving transistor TDR is connected to a first electrode of the emission transistor TEM, the micro LED (ED) is connected to a second electrode, and the emission signal EM may be applied to a gate electrode. The emission signal EM applied to the gate electrode of the emission transistor TEM may be a pulse width modulation signal which changes in every frame, but the exemplary embodiments of the present disclosure are not limited thereto.

A first electrode of the micro LED (ED) is connected to the second electrode of the emission transistor TEM and a second electrode may be connected to the ground. For example, the first electrode is an anode electrode and the second electrode may be a cathode electrode, but the exemplary embodiments of the present disclosure are not limited thereto.

Each of the driving transistor TDR and the emission transistor TEM may be an n-type transistor or a p-type transistor.

The driving transistor TDR is turned on by a scan signal SC applied from the timing controller T-CON to the micro driver (μDriver) and the emission transistor TEM is turned on by the emission signal EM. By doing this, the driving current is applied to the micro LED (ED) via the driving transistor TDR and the emission transistor TEM by the high potential power voltage VDD applied to the first electrode of the driving transistor TDR so that the micro LED (ED) may emit light.

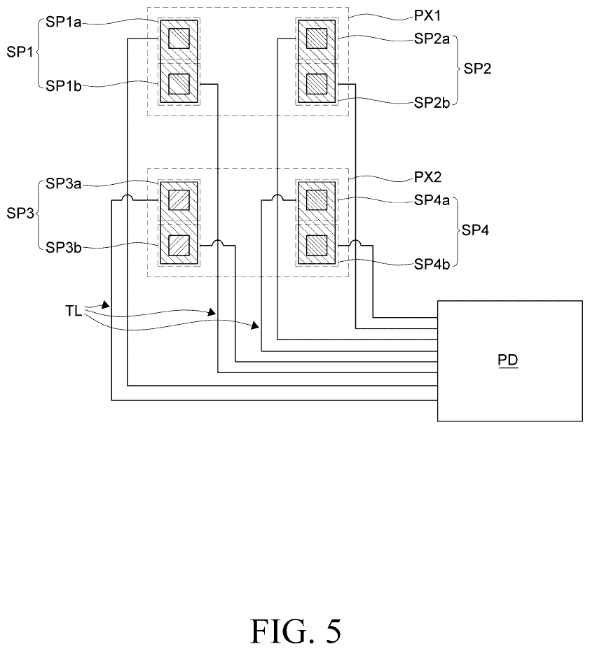

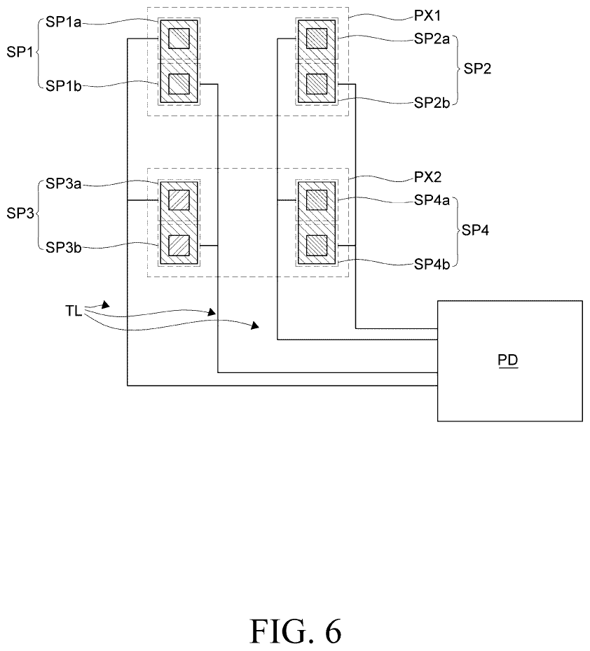

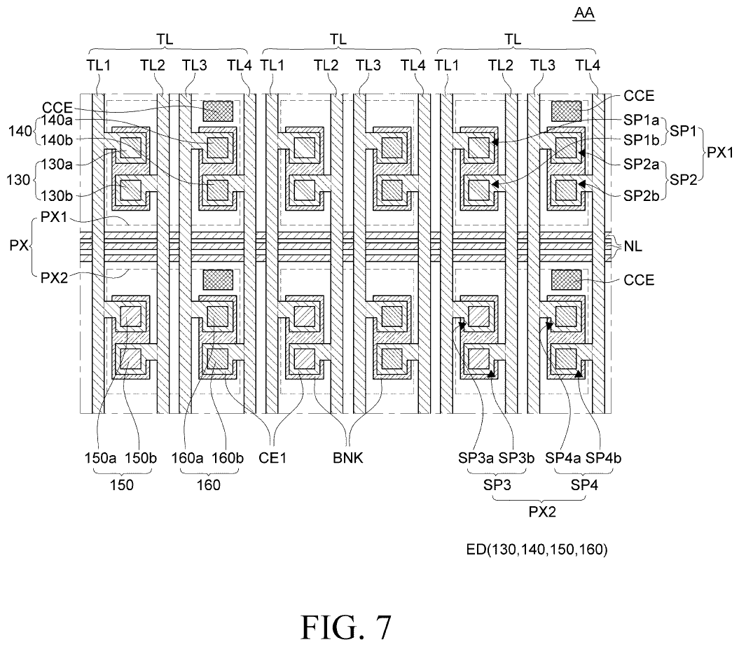

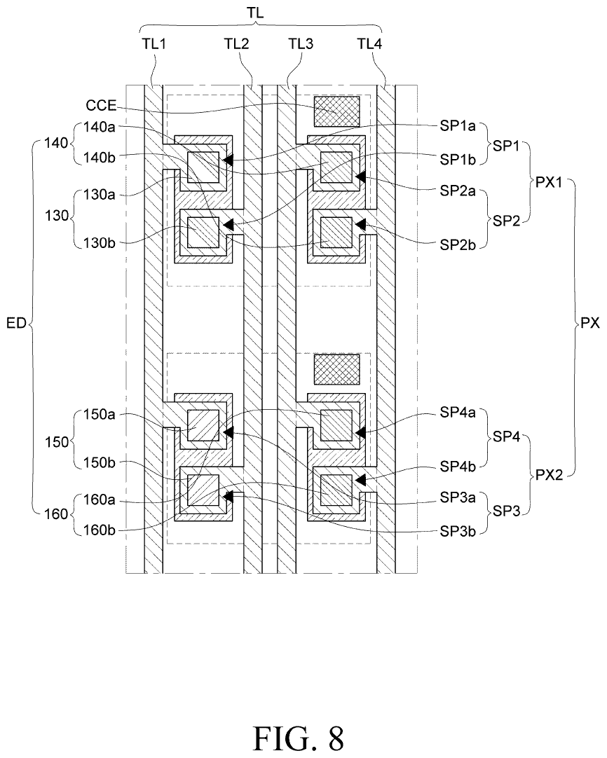

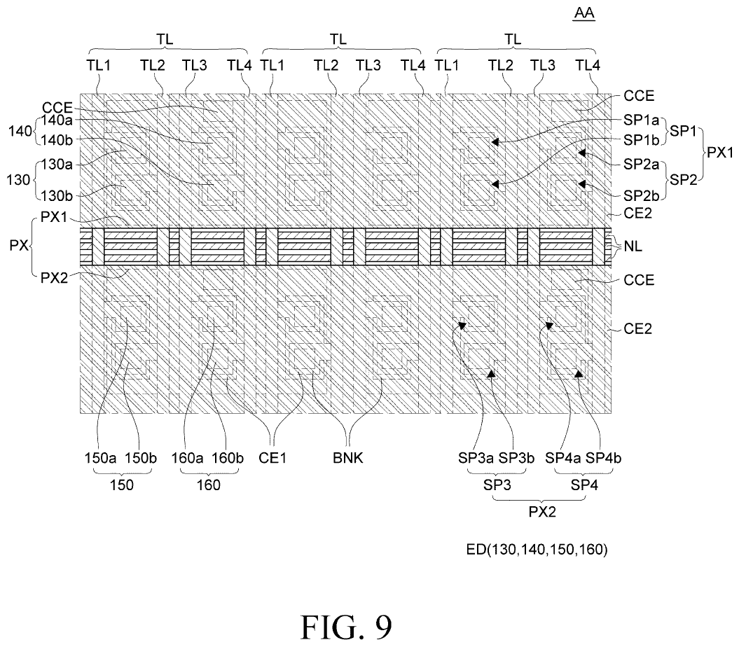

FIGS. 5 and 6 are schematic diagrams of a display device according to an exemplary embodiment of the present disclosure. FIGS. 7 to 9 are plan views of a display device according to an exemplary embodiment of the present disclosure. For example, FIGS. 5 and 6 are views illustrating a connection structure of a plurality of sub pixels and a pixel driving circuit PD. For example, FIG. 7 is an enlarged plan view of an active area including a plurality of pixels PX. For example, FIG. 8 is an enlarged plan view of an active area including one first pixel PX1 and one second pixel PX2. For example, FIG. 9 is an enlarged plan view of an active area including a plurality of pixels PX. In FIGS. 7 and 8, only a plurality of signal lines TL, a plurality of communication lines NL, a plurality of first electrodes CE1, a plurality of banks BNK, and a plurality of micro LEDs (ED) are illustrated, but the exemplary embodiments of the present disclosure are not limited thereto. FIG. 9 is an enlarged plan view in which a plurality of second electrodes CE2 is additionally disposed to FIG. 7.

Referring to FIGS. 5 to 7, a plurality of pixels PX which is configured by a plurality of sub pixels may be disposed in the active area AA. Each of the plurality of sub pixels includes a micro LED (ED) and may independently emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third may be a blue sub pixel. The types of the plurality of sub pixels are illustrative, but the exemplary embodiments of the present disclosure are not limited thereto.

The plurality of pixels PX may include a plurality of first pixels PX1 and a plurality of second pixels PX2. The plurality of first pixels PX1 and the plurality of second pixels PX2 may include sub pixels having different combinations. For example, the plurality of first pixels PX1 includes a plurality of first sub pixels SP1 and a plurality of second sub pixels SP2 and the plurality of second pixels PX2 may include a plurality of third sub pixels SP3 and a plurality of fourth sub pixels SP4. The plurality of first pixels PX1 and the plurality of second pixels PX2 may be disposed in different rows. For example, rows in which a plurality of first pixels PX1 is disposed and rows in which a plurality of second pixels PX2 is disposed may be alternately disposed and in the same row, the plurality of first pixels PX1 and the plurality of second pixels PX2 may be alternately disposed. However, the number and placements of the plurality of first pixels PX1 and the plurality of second pixels PX2 are illustrative, but the exemplary embodiments of the present disclosure are not limited thereto.

Each of the plurality of first pixels PX1 may include one or more first sub pixels SP1 and one or more second sub pixels SP2. For example, one first pixel PX1 may include one pair of first sub pixels SP1 and one pair of second sub pixels SP2. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. For example, one first pixel PX1 may include a 1-1-th sub pixel SP1a and a 1-2-th sub pixel SP1b and a 2-1-th sub pixel SP2a and a 2-2-th sub pixel SP2b, but the exemplary embodiments of the present disclosure are not limited thereto.

Each of the plurality of second pixels PX2 may include one or more third sub pixels SP3 and one or more fourth sub pixels SP4. For example, one second pixel PX2 may include one pair of third sub pixels SP3 and one pair of fourth sub pixels SP4. One pair of third sub pixels SP3 may be configured by a 3-1-th sub pixel SP3a and a 3-2-th sub pixel SP3b and one pair of fourth sub pixels SP4 may be configured by a 4-1-th sub pixel SP4a and a 4-2-th sub pixel SP4b. For example, one second pixel PX2 may include a 3-1-th sub pixel SP3a and a 3-2-th sub pixel SP3b and a 4-1-th sub pixel SP4a and a 4-2-th sub pixel SP4b, but the exemplary embodiments of the present disclosure are not limited thereto.

The plurality of sub pixels which forms one pixel PX may be disposed in various ways. For example, in one first pixel PX1, one pair of first sub pixels SP1 is disposed in the same column and one pair of second sub pixels SP2 may be disposed in the same column. In one first pixel PX1, one pair of first sub pixels SP1 is disposed to be adjacent to each other in the column direction and one pair of second sub pixels SP2 is disposed to be adjacent to each other in the column direction. In one second pixel PX2, one pair of third sub pixels SP3 is disposed in the same column and one pair of fourth sub pixels SP4 may be disposed in the same column. In one second pixel PX2, one pair of third sub pixels SP3 is disposed to be adjacent to each other in the column direction and one pair of fourth sub pixels SP4 may be disposed to be adjacent to each other in the column direction.

Further, the first sub pixel SP1 and the second sub pixel SP2 of the first pixel PX1 may be disposed in the same row and the third sub pixel SP3 and the fourth sub pixel SP4 of the second pixel PX2 may be disposed in the same row. For example, the first sub pixel SP1 and the second sub pixel SP2 are disposed to be adjacent to each other in the row direction and in one row, the first sub pixels SP1 and the second sub pixels SP2 may be alternately disposed. For example, the third sub pixel SP3 and the fourth sub pixel SP4 may be disposed to be adjacent to each other in the row direction and in one row, the third sub pixels SP3 and the fourth sub pixels SP4 may be alternately disposed.

In the meantime, one pair of first sub pixels SP1 emits red light, one pair of second sub pixels SP2 and one pair of fourth sub pixels SP4 emit green light, and one pair of third sub pixels SP3 emits blue light. Various color light including white light may be implemented by a combination of red light, green light, and blue light emitted from the first sub pixel SP1, the second sub pixel SP2, the third sub pixel SP3, and the fourth sub pixel SP4. The first sub pixel SP1, the second sub pixel SP2, the third sub pixel SP3, and the fourth sub pixel SP4 are disposed to be adjacent to each other and form an RG BG pentile disposition. For example, the first sub pixel SP1 which emits red light may be disposed to be adjacent to the second sub pixel SP2 which emits green light and the third sub pixel SP3 which emits blue light, respectively. The first sub pixel SP1 is disposed to be adjacent to the second sub pixel SP2 in one direction and is disposed to be adjacent to the third sub pixel SP3 in a direction different from one direction. The third sub pixel SP3 which emits blue light may be disposed to be adjacent to the first sub pixel SP1 which emits red light and the fourth sub pixel SP4 which emits green light, respectively. The third sub pixel SP3 is disposed to be adjacent to the first sub pixel SP1 in one direction and is disposed to be adjacent to the fourth sub pixel SP4 in a direction different from one direction. However, a number and a placement of the plurality of sub pixels which configures one pixel PX are illustrative, but the exemplary embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED (ED). Therefore, the anode voltage from the signal line TL may be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display device 1000. Further, a circuit which is disposed in each of the plurality of sub pixels is integrated in one pixel driving circuit PD so that highly efficient low power driving is possible.

Referring to FIGS. 5 and 6, a plurality of signal lines TL between the plurality of sub pixels and the pixel driving circuit may be configured in various forms. The plurality of signal lines TL may be connected to the plurality of sub pixels one to one and some sub pixels may share the plurality of signal lines TL.

Referring to FIG. 5, each of the plurality of sub pixels is connected to different signal lines TL to be applied with an anode voltage from the pixel driving circuit PD. For example, each of the 1-1-th sub pixel SP1a, the 1-2-th sub pixel SP1b, the 2-1-th sub pixel SP2a, the 2-2-th sub pixel SP2b, the 3-1-th sub pixel SP3a, the 3-2-th sub pixel SP3b, the 4-1-th sub pixel SP4a, and the 4-2-th sub pixel SP4b are connected to a different signal line TL to be applied with an anode voltage from the pixel driving circuit PD. The plurality of sub pixels and the plurality of signal lines TL may be connected to each other one to one and the plurality of sub pixels may be independently controlled.

Referring to FIG. 6, some sub pixels disposed in the same column share the signal line TL. For example, the 1-1-th sub pixel SP1a and the 3-1-th sub pixel SP3a are connected to the same signal line TL and the 1-2-th sub pixel SP1b and the 3-2-th sub pixel SP3b may be connected to the same signal line TL. The 2-1-th sub pixel SP2a and the 4-1-th sub pixel SP4a are connected to the same signal line TL and the 2-2-th sub pixel SP2b and the 4-2-th sub pixel SP4b may be connected to the same signal line TL. Further, the anode voltage is applied to each of the plurality of sub pixels which shares the same signal line TL at different timings. For example, the anode voltage is applied to the 1-1-th sub pixel SP1a and the 3-1-th sub pixel SP3a connected to the same signal line TL at different timings to be independently controlled. Accordingly, when some sub pixels share the signal line TL, the plurality of sub pixels may be individually controlled by means of time-division operation.

Hereinafter, the display device 1000 according to the present disclosure will be described by assuming that the plurality of sub pixels shares the signal line TL as illustrated in FIG. 6, but the exemplary embodiments of the present disclosure are not limited thereto.

Referring to FIG. 7, the plurality of signal lines TL may include a first signal line TL1, a second signal line TL2, a third signal line TL3, and a fourth signal line TL4. The first signal line TL1 and the second signal line TL2 may be electrically connected to one pair of first sub pixels SP1 and one pair of third sub pixels SP3, respectively. The third signal line TL3 and the fourth signal line TL4 may be electrically connected to one pair of second sub pixels SP2 and one pair of fourth sub pixels SP4, respectively.

The first signal line TL1 is disposed in one of one pair of first sub pixels SP1 and one of one pair of third sub pixels SP3 and the second signal line TL2 may be disposed in the other one of one pair of first sub pixels SP1 and the other one of one pair of third sub pixels SP3. The first signal line TL1 may be electrically connected to one first sub pixel SP1, between one pair of first sub pixels SP1, for example, to the first electrode CE1 of the 1-1-th sub pixel SP1a. The first signal line TL1 may be electrically connected to one third sub pixel SP3, between one pair of third sub pixels SP3, for example, to the first electrode of the 3-1-th sub pixel SP3a. The second signal line TL2 may be electrically connected to the other first sub pixel SP1, between one pair of first sub pixels SP1, for example, to the first electrode CE1 of the 1-2-th sub pixel SP1b. The second signal line TL2 may be electrically connected to the other third sub pixel SP3, between one pair of third sub pixels SP3, for example, to the first electrode CE1 of the 3-2-th sub pixel SP3b.

The third signal line TL3 is disposed in one of one pair of second sub pixels SP2 and one of one pair of fourth sub pixels SP4 and the fourth signal line TL4 may be disposed in the other one of one pair of second sub pixels SP2 and the other one of one pair of fourth sub pixels SP4. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1-th sub pixel SP2a. The third signal line TL3 may be electrically connected to one fourth sub pixel SP4, between one pair of fourth sub pixels SP4, for example, to the first electrode of the 4-1-th sub pixel SP4a. The fourth signal line TL4 may be electrically connected to the other second sub pixel SP2, between one pair of second sub pixels SP2, for example, to the first electrode CE1 of the 2-2-th sub pixel SP2b. The fourth signal line TL4 may be electrically connected to the other fourth sub pixel SP4, between one pair of fourth sub pixels SP4, for example, to the first electrode CE1 of the 4-2-th sub pixel SP4b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. For example, the plurality of communication lines extends to a row direction in an area between the first pixel PX1 and the second pixel PX2. The plurality of communication lines NL is disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display device 1000. The plurality of micro LEDs (ED) may be transferred onto the plurality of banks BNK in the transfer process of the plurality of micro LEDs (ED). The plurality of banks BNK may be a bank pattern or a structure, but the exemplary embodiments of the present disclosure are not limited thereto.

A bank BNK of the first sub pixel SP1, a bank BNK of the second sub pixel SP2, a bank BNK of the third sub pixel SP3, and a bank BNK of the fourth sub pixel SP4 may be disposed to be spaced apart from each other. The bank BNK of the first sub pixel SP1, the bank BNK of the second sub pixel SP2, the bank BNK of the third sub pixel SP3, and the bank of the fourth sub pixel SP4 may be configured to be separated from each other. Therefore, the banks BNK of the first sub pixel SP1, the second sub pixel SP2, the third sub pixel SP3, and the fourth sub pixel SP4 to which different types of micro LEDs (ED) are transferred may be easily identified.

The bank BNK of the 1-1-th sub pixel SP1a and the bank BNK of the 1-2-th sub pixel SP1b are connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed may be connected to each other or spaced apart or separated from each other. Further, the bank BNK of the 2-1-th sub pixel SP2a and the bank BNK of the 2-2-th sub pixel SP2b are connected to each other, spaced apart or separated from each other. The bank BNK of the 3-1-th sub pixel SP3a and the bank BNK of the 3-2-th sub pixel SP3b are connected to each other, spaced apart or separated from each other. The bank BNK of the 4-1-th sub pixel SP4a and the bank BNK of the 4-2-th sub pixel SP4b are connected to each other or spaced apart or separated from each other. Accordingly, the banks BNK of one pair of first sub pixels SP1, the banks BNK of one pair of second sub pixels SP2, the banks BNK of one pair of third sub pixels SP3, and the banks BNK of one pair of fourth sub pixels SP4 are formed in various forms, but the exemplary embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic material, but the exemplary embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the first signal line TL1. A part of the first electrode CE1 of the 3-2-th sub pixel SP3b extends to the other area of the 3-2-th sub pixel SP3b to be electrically connected to the second signal line TL2. A part of the first electrode CE1 of the 4-1-th sub pixel SP4a extends to one area of the 4-1-th sub pixel SP4a to be electrically connected to the third signal line TL3. A part of the first electrode CE1 of the 4-2-th sub pixel SP4b extends to the other area of the 4-2-th sub pixel SP4b to be electrically connected to the fourth signal line TL4.

The first electrode CE1 is electrically connected to the anode electrode 134 of the micro LED (ED) and transmits an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel (PX) electrode, but the exemplary embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the exemplary embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the exemplary embodiments of the present disclosure are not limited thereto.

The micro LED (ED) may be disposed in each of the plurality of sub pixels. The plurality of micro LEDs (ED) may be disposed on the bank BNK and the first electrode CE1. The plurality of micro LEDs (ED) is disposed on the first electrode CE1 and is electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) may include a first micro LED 130, a second micro LED 140, a third micro LED 150, and a fourth micro LED 160. The first micro LED 130 may be disposed in the first sub pixel SP1. The second micro LED 140 may be disposed in the second sub pixel SP2. The third micro LED 150 may be disposed in the third sub pixel SP3. The fourth micro LED 160 may be disposed in the fourth sub pixel SP4. For example, any one of the first micro LED 130, the second micro LED 140, the third micro LED 150, and the fourth micro LED 160 is a red micro LED (ED), another is a green micro LED (ED), and the remaining is a blue micro LED (ED), but the exemplary embodiments of the present disclosure are not limited thereto. For example, the first micro LED 130 is a red micro LED (ED), the second micro LED 140 and the fourth micro LED 160 are green micro LEDs (ED), and the third micro LED 150 is a blue micro LED (ED), but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b. The fourth micro LED 160 may include a 4-1-th micro LED 160a disposed in the 4-1-th sub pixel SP4a and a 4-2-th micro LED 160b disposed in the 4-2-th sub pixel SP4b.

Referring to FIGS. 7 to 9 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixels may share the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes CE2 of at least some pixels PX, among the plurality of pixels PX disposed on the same row, may be connected to each other. For example, one second electrode is disposed in the plurality of first pixels PX1 disposed in the same row and one second electrode may be disposed in the plurality of second pixels PX2 disposed in the same row. As another example, one second electrode CE2 may be disposed in every n pixels PX.

For example, some of the second electrodes CE2 of the plurality of sub pixels is spaced apart or separated from each other. For example, a second electrode CE2 connected to first pixels PX1 in a n-th row and a second electrode CE2 connected to second pixels PX2 in a n+1-th row are spaced apart or separated from each other. For example, the plurality of second electrodes CE2 is spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 is disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 is configured by a transparent conductive material so that light emitted from the micro LED (ED) travels toward the top of the second electrode CE2. For example, the second electrode CE2 may be configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED (ED) is used, a plurality of micro LEDs is formed on a wafer and the micro LED is transferred onto the substrate 110 of the display device 1000 to manufacture the display device 1000. However, during the process of transferring the plurality of micro LEDs (ED) having a micro size from the wafer to the substrate 110, various defects may be caused. For example, in some sub pixels, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of same type micro LEDs may be transferred in one sub pixel. A lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, only the 1-1-th micro LED 130a is used, but the 1-2-th micro LED 130b is not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b may be used. Accordingly, even though the plurality of same type micro LEDs (ED) is transferred to one pixel PX, finally, only one micro LED (ED) may be used.

Therefore, any one of one pair of micro LEDs (ED) is a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized or reduced.

For example, the 1-1-th micro LED 130a and the 2-1-th micro LED 140a which are transferred to one first pixel PX1 are used as main micro LEDs (ED) and the 1-2-th micro LED 130b and the 2-2-th micro LED 140b may be used as redundancy micro LEDs (ED). The 3-1-th micro LED 150a and the 4-1-th micro LED 160a which are transferred to one second pixel PX2 are used as main micro LEDs (ED) and the 3-2-th micro LED 150b and the 4-2-th micro LED 160b are used as redundancy micro LEDs (ED).

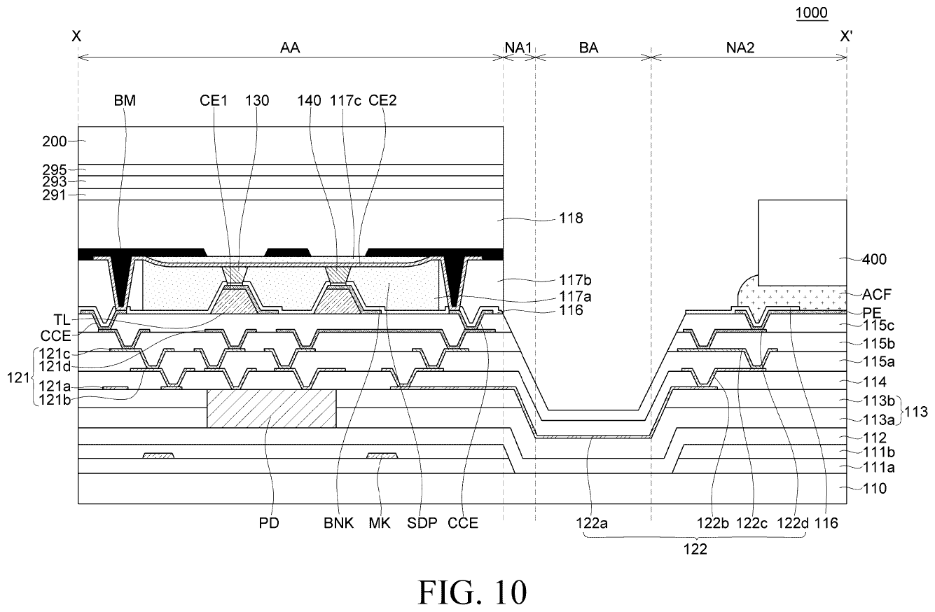

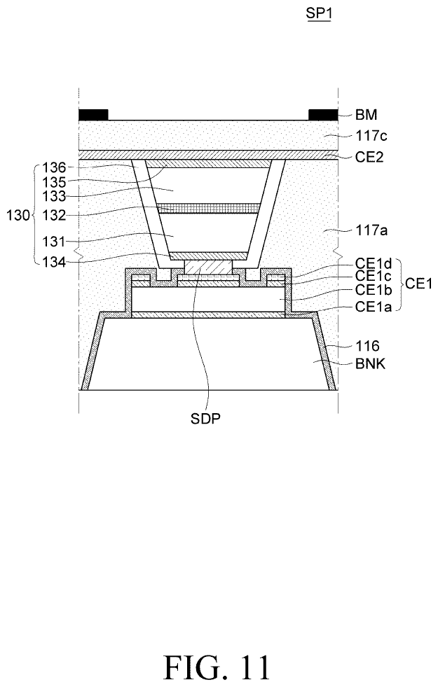

FIG. 10 is a cross-sectional view of a display device according to an exemplary embodiment of the present disclosure. FIG. 11 is a cross-sectional view of a display device according to an exemplary embodiment of the present disclosure. For example, FIG. 10 is a cross-sectional view taken along X-X′ of FIG. 3 which is a cross-sectional view of an active area AA, a first non-active area NA1, a bending area BA, and a second non-active area NA2. For example, FIG. 11 is an enlarged cross-sectional view of a first sub pixel.

Referring to FIG. 10, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or a plurality of layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A protection layer 113 may be disposed on the adhesive layer 112 and the pixel driving circuit PD. The protection layer 113 may be disposed so as to enclose the pixel driving circuit PD, but the exemplary embodiments of the present disclosure are not limited thereto. For example, the protection layer 113 may be disposed so as to cover at least a part of a side surface of the pixel driving circuit PD. As another example, the protection layer 113 may be disposed so as to cover at least a part of a top surface of the pixel driving circuit PD.

The protection layer 113 may include one or more organic insulating layers. For example, the protection layer 113 may include a first protection layer 113a disposed on the adhesive layer 112 and a second protection layer 113b disposed on the first protection layer 113a. For example, the first protection layer 113a and the second protection layer 113b may be disposed so as to enclose a side surface of the pixel driving circuit PD. For example, the second protection layer 113b may be disposed so as to cover at least a part of a top surface of the pixel driving circuit PD. For example, at least one of the first protection layer 113a and the second protection layer 113b of the protection layer 113 disposed on the bending area BA may be omitted. For example, the first protection layer 113a is entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed. However, the protection layer 113 may be formed by a single layer, but the exemplary embodiments of the present disclosure are not limited thereto.

Each of the first protection layer 113a and the second protection layer 113b of the protection layer may be configured by an organic insulating material, but the exemplary embodiments of the present disclosure are not limited thereto. For example, the first protection layer 113a and the second protection layer 113b may be configured by a photo resist, polyimide (PI), or photo acrylic-based material, but the exemplary embodiments of the present disclosure are not limited thereto. For example, the first protection layer 113a and the second protection layer 113b may be an over coating layer or an insulating layer, but the exemplary embodiments of the present disclosure are not limited thereto.

According to the present specification, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121d, but the exemplary embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, an additional protection layer may be further disposed on the second protection layer 113b. For example, a third protection layer 114 may be further disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic-based material, but the exemplary embodiments of the present disclosure are not limited thereto. For example, the first protection layer 113a, the second protection layer 113b, and the third protection layer 114 may be configured by the same material, but the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114. However, the exemplary embodiments of the present disclosure are not limited thereto. A voltage output from the pixel driving circuit PD may be transmitted to the first electrode CE1 or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the exemplary embodiments of the present disclosure are not limited thereto. The first insulating layer 115a may be configured by an organic insulating material, but the exemplary embodiments of the present disclosure are not limited thereto. For example, the first insulating layer 115a may be configured by a photo resist, polyimide (PI), or photo acrylic-based material, but the exemplary embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may be configured by an organic insulating material, but the exemplary embodiments of the present disclosure are not limited thereto. For example, the second insulating layer 115b is configured by a photo resist, polyimide (PI), or photo acrylic-based material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to the present specification, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection lines 122a, a 2-2-th connection lines 122b, a 2-3-th connection lines 122c, and a 2-4-th connection lines 122d.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) 400 and the printed circuit board 500 to the pad unit PAD to the pixel driving circuit PD of the active area AA. For example, the 2-1-th connection line 122a extends from the second non-active area NA2 to the first non-active area NA1 and may be electrically connected to any one of the 1-1-th connection line 121a, the 1-2-th connection line 121b, the 1-3-th connection line 121c, and the 1-4-th connection line 121d of the plurality of first connection lines 121. For example, the 2-1-th connection line 122a may be directly connected to the 1-1-th connection line 121a disposed on the same layer or may be connected to the 1-2-th connection line 121b disposed on a different layer through a contact hole of the third protection layer 114, but is not limited thereto.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) 400 and the printed circuit board 500 may be transmitted to the 2-1-th connection line 122a through the 2-2-th connection line 122b.

The 2-3-th connection lines 122c may be disposed on the first insulating layer 115a. The 2-3-th connection lines 122c may be disposed in the second non-active area NA2. The 2-3-th connection lines 122c may be electrically connected to the 2-2-th connection line 122b through a contact hole of the first insulating layer 115a. Accordingly, a signal from the flexible circuit board (or flexible film) 400 and the printed circuit board 500 may be transmitted to the 2-1-th connection line 122a through the 2-3-th connection line 122c and the 2-2-th connection line 122b.

The 2-4-th connection lines 122d may be disposed on the second insulating layer 115b. The 2-4-th connection lines 122d may be disposed in the second non-active area NA2. The 2-4-th connection lines 122d may be electrically connected to the 2-3-th connection line 122c through a contact hole of the second insulating layer 115b. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the exemplary embodiments of the present disclosure are not limited thereto. For example, the third insulating layer 115c may be configured by a photo resist, polyimide (PI), or photo acrylic-based material, but the exemplary embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LED (ED) may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 11, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the exemplary embodiments of the present disclosure are not limited thereto.

According to the present specification, some conductive layer having a good reflection efficiency, among a plurality of conductive layers which configures the first electrode CE1 may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remains and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has corrosion resistance and acid resistance. However, the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the exemplary embodiments of the present disclosure are not limited thereto.

According to the present specification, the signal line TL, the contact electrode CCE, and the pad electrode PE disposed on the same layer as the first electrode CE1 may be configured by a plurality of layers of conductive materials, but the exemplary embodiment of the present disclosure are not limited thereto. For example, the signal line TL, the contact electrode CCE, and the pad electrode PE may be formed of a plurality of layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, the solder pattern SDP may be disposed on the first electrode CE1. The solder pattern SDP may bond the micro LED (ED) to the first electrode CE1. The solder pattern SDP may bond the first electrode CE1 and the anode electrode 134 of the micro LED (ED) to be electrically connected to each other. The first electrode CE1 and the micro LED (ED) may be electrically connected through eutectic bonding using the solder pattern SDP, but the exemplary embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) may be bonded to the solder pattern SDP and the first electrode CE1 using the eutectic bonding without a separate adhesive material. For example, the solder pattern SDP may be configured by indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

According to the present specification, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or a plurality of layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED (ED) may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3. A fourth micro LED 160 may be disposed in the fourth sub pixel SP4.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 11, the first micro LED 130 may include an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 is an n-type impurity doped semiconductor layer and the other one is a p-type impurity doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Sc), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQW) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 has a multi quantum well (MQW) structure having a well layer and a barrier layer with a band gap higher than the well layer. For example, in the active layer 132, InGaN is configured as a well layer and an AlGaN layer is configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the exemplary embodiments of the present disclosure are not limited thereto. For example, the cathode electrode 135 may be configured by a material, such as indium tin oxide (ITO), indium zinc oxide (IZO), indium gallium zinc oxide (IGZO), but the exemplary embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the exemplary embodiments of the present disclosure are not limited thereto.

As another example, the encapsulation film 136 may have a structure in which a reflective material is dispersed in a resin layer, but the exemplary embodiments of the present disclosure are not limited thereto. For example, the encapsulation film 136 may be manufactured with reflectors with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present specification, it is described that the micro LED (ED) has a vertical structure, but the exemplary embodiments of the present disclosure are not limited thereto. For example, the micro LED (ED) may have a lateral structure or a flip-chip structure.

The first micro LED 130 has been described with reference to FIG. 11 and the second micro LED 140, the third micro LED 150 and the fourth micro LED 160 may have the substantially same structure as the first micro LED 130. For example, the second micro LED 140, the third micro LED 150 and the fourth micro LED 160 may be substantially the same as the first semiconductor layer 131, the active layer 132, the second semiconductor layer 133, the anode electrode 134, the cathode electrode 135, and the encapsulation film 136 of the first micro LED 130.

According to the present specification, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a first direction and may be spaced apart from each other in a second direction. For example, the first optical layer 117a may be disposed so as to enclose side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a may include an organic insulating material in which micro particles are dispersed, but the exemplary embodiments of the present disclosure are not limited thereto. For example, the first optical layer 117a may be configured by siloxane in which micro metal particles, such as titanium dioxide (TiO2) particles, are dispersed, but the exemplary embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the exemplary embodiments of the present disclosure are not limited thereto. For example, the first optical layer 117a is disposed in each of the plurality of pixels PX or the plurality of pixels PX may share one first optical layer 117a. For example, the first optical layer 117a is disposed in each of the plurality of first pixels PX1 or the plurality of first pixels PX1 which is disposed on the same row may share one first optical layer 117a. For example, the first optical layer 117a is disposed in each of the plurality of second pixels PX2 or the plurality of second pixels PX2 which is disposed on the same row may share one first optical layer 117a. As another example, each of the plurality of sub pixels separately may include the first optical layer 117a, but the exemplary embodiments of the present disclosure are not limited thereto.

According to the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. For example, the first optical layer 117a is disposed in each of the plurality of first pixels PX1 and the second optical layer 117b may be disposed between the first optical layers 117a of the plurality of first pixels PX1, that is, between the plurality of first pixels PX1. The first optical layer 117a is disposed in each of the plurality of second pixels PX2 and the second optical layer 117b may be disposed between the first optical layers 117a of the plurality of second pixels PX2, that is, between the plurality of second pixels PX2. Further, when the plurality of first pixels PX1 shares one first optical layer 117a and the plurality of second pixels PX2 shares one first optical layer 117a, the second optical layer 117b may be disposed between the first optical layer 117a of the plurality of first pixels PX1 and the first optical layer 117a of the plurality of second pixels PX2. However, the exemplary embodiments of the present disclosure are not limited thereto. For example, the second optical layer 117b may be a diffusion layer, a diffusion window, or a window diffusion layer, but the exemplary embodiments of the present disclosure are not limited thereto.

The second optical layer 117b may be configured by an organic insulating material, but the exemplary embodiments of the present disclosure are not limited thereto. The second optical layer 117b may be configured by the same material as the first optical layer 117a, but the exemplary embodiments of the present disclosure are not limited thereto. For example, the first optical layer 117a may include micro particles, but the second optical layer 117b does not include micro particles. For example, the second optical layer 117b is configured by siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135. For example, the second electrode CE2 may overlap the first optical layer 117a. For example, the second electrode may cover a plane surface at the outside of the first optical layer 117a.

The second electrode CE2 may continuously extend in a first direction of the substrate 110. Accordingly, the second electrode may be commonly connected to the plurality of first pixels PX1 disposed in the first direction of the substrate 110. The second electrode may be commonly connected to the plurality of second pixels PX2 disposed in the first direction of the substrate 110. For example, the second electrode CE2 is commonly connected to the plurality of pixels PX.

According to the present specification, the second electrode CE2 may continuously extend on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display device 1000, an area in which the interval between the plurality of micro LEDs (ED) is not uniform may be caused due to the process deviation. When the interval between the plurality of micro LEDs (ED) is not uniform, an emission area of each of the plurality of micro LEDs (ED) is not uniformly disposed so that the mura may be visible to a user. Accordingly, the third optical layer 117c which is configured to uniformly diffuse light is configured above the plurality of micro LEDs (ED) so that light emitted from some micro LED (ED) which is visible as mura may be reduced. Accordingly, light emitted from the plurality of micro LEDs (ED) is uniformly diffused by the third optical layer 117c to be extracted to the outside of the display device 1000 so that the luminance uniformity of the display device 1000 may be improved.

The third optical layer 117c may be configured by an organic insulating material in which micro particles are dispersed, but the exemplary embodiments of the present disclosure are not limited thereto. For example, the third optical layer 117c may be configured by siloxane in which micro metal particles, such as titanium dioxide (TiO2) particles, are dispersed, but the exemplary embodiments of the present disclosure are not limited thereto. For example, the third optical layer 117c is configured by the same material as the first optical layer 117a, but the exemplary embodiments of the present disclosure are not limited thereto. For example, the third optical layer 117c may be a diffusion layer or a upward diffusion layer, but the exemplary embodiments of the present disclosure are not limited thereto.

According to the present specification, light from the plurality of micro LEDs (ED) is scattered by micro particles dispersed in the third optical layer 117c to be emitted to the outside of the display device 1000. The third optical layer 117c uniformly mixes light emitted from the plurality of micro LEDs (ED) to further improve the luminance uniformity of the display device 1000. Further, the light extraction efficiency of the display device 1000 may be improved by light scattered from the plurality of micro particles so that the display device 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the exemplary embodiments of the present disclosure are not limited thereto. For example, the black matrix BM may be configured by an organic insulating material to which black pigment or black dye are added, but the exemplary embodiments of the present disclosure are not limited thereto.

The black matrix BM includes a plurality of transmission holes. The plurality of transmission holes is openings which overlap micro LEDs (ED) of a plurality of sub pixels. Light emitted from the plurality of micro LEDs (ED) may be extracted to the outside of the display panel 100 through the plurality of transmission holes. The plurality of transmission holes may be disposed so as to overlap some sub pixel of the plurality of sub pixels included in one pixel PX. For example, the plurality of transmission holes may be formed so as to overlap only one of one pair of first sub pixels SP1, one of one pair of second sub pixels SP2, one of one pair of third sub pixels SP3, and one of one pair of fourth sub pixels SP4. At this time, the plurality of remaining sub pixels in which the plurality of transmission holes is not formed may be a sub pixel including a defective main micro LED (ED) or a sub pixel including a redundancy micro LED (ED), but the exemplary embodiments of the present disclosure are not limited thereto.

The plurality of transmission holes is larger than the plurality of micro LEDs (ED). For example, on the plane, the plurality of transmission holes is formed to be wider than the plurality of micro LEDs (ED) to ensure a margin for a process deviation.

A planar surface shape of the plurality of transmission holes may correspond to a planar surface shape of the plurality of micro LEDs (ED). For example, when the planar surface shape of the plurality of micro LEDs (ED) is a rectangle, the planar surface shape of the plurality of transmission holes may be a rectangle. However, the planar surface shape of the plurality of transmission holes and the planar surface shape of the plurality of micro LEDs (ED) may be different from each other, but are not limited thereto.

In the active area AA, a cover layer 118 may be disposed on the black matrix BM. The cover layer 118 may protect configurations below the cover layer 118. For example, the cover layer 118 may be configured by an organic insulating material, but the exemplary embodiments of the present disclosure are not limited thereto. For example, the cover layer 118 may be configured by a photo resist, polyimide (PI), or photo acrylic-based material, but the exemplary embodiments of the present disclosure are not limited thereto. For example, the cover layer 118 may be an over coating layer or an insulating layer, but the exemplary embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present specification, a plurality of pad electrodes PE may be disposed on the third insulating layer 115c in the second non-active area NA2. For example, at least a part of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400, the flexible circuit board (or flexible film) 400 may be attached or bonded to the plurality of pad electrodes PE. For example, the adhesive layer ACF may be anisotropic conductive film, but the exemplary embodiments of the present disclosure are not limited thereto.

The flexible circuit board (or flexible film) 400 may be disposed on the adhesive layer ACF. The flexible circuit board (or flexible film) 400 may be electrically connected to the plurality of pad electrodes PE through the adhesive layer ACF. Accordingly, a signal output from the flexible circuit board (or flexible film) 400 and the printed circuit board 500 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

In the display device 1000 according to the exemplary embodiment of the present disclosure, the plurality of pixels PX includes a plurality of first pixels PX1 configured by a first sub pixel SP1 and a second sub pixel SP2 and a plurality of second pixels PX2 configured by a third sub pixel SP3 and a fourth sub pixel SP4. Accordingly, a high resolution display device may be implemented. Each of the plurality of pixels PX is configured by the first sub pixel SP1 and the second sub pixel SP2 or configured by only the third sub pixel SP3 and the fourth sub pixel SP4 so that an area required for one pixel PX may be reduced. For example, it may be an RG/BG pentile disposition structure in which the first pixel PX1 is configured by the first sub pixel SP1 and the second sub pixel SP2 which emit red light and green light and the second pixel PX2 is configured by the third sub pixel SP3 and the fourth sub pixel SP4 which emit blue and green light. Specifically, as compared with an RGB stripe disposition structure in which one pixel PX is configured by red, green, and blue sub pixels, in the display device 1000 according to the exemplary embodiment of the present disclosure, the number of sub pixels included in one pixel PX is small. Therefore, the number of the plurality of pixels PX which may be formed in the display device may be increased and a display device 1000 with a high pixel per inch (PPI) may be implemented.

In the display device 1000 according to the exemplary embodiment of the present disclosure, an interval between the plurality of sub pixels required for the transfer process of the plurality of micro LEDs (ED) may be ensured. The plurality of micro LEDs (ED) may be transferred to the display device 1000 by separately performing a transfer process for transferring a main micro LED (ED) and a process of transferring a redundancy micro LED (ED). For example, the plurality of first micro LEDs 130 may be disposed in the display device 1000 by a primary transfer process of transferring only the plurality of 1-1-th micro LEDs 130a and a secondary transfer process of transferring only the plurality of 1-2-th micro LEDs 130b. A donor substrate on which the plurality of micro LEDs (ED) is disposed is disposed on the display panel 100 on which the plurality of banks BNK and the plurality of first electrodes CE1 are formed to transfer the plurality of micro LEDs (ED) onto the bank BNK and the first electrode CE1. The plurality of banks BNK protrudes more than the other configuration of the display panel 100 so that the micro LED (ED) may be easily transferred onto the plurality of banks BNK. At this time, if the interval between the plurality of banks BNK is not sufficiently ensured, a micro LED (ED) which is not a transferring target is in contact with the bank BNK to be transferred thereonto and a micro LED (ED) which has been already transferred onto the bank BNK and the micro LED (ED) of a donor may interfere with each other. Therefore, the interval between the plurality of banks BNK may be determined in consideration of a margin of each of the plurality of transfer processes. In the display device 1000 according to the exemplary embodiment of the present disclosure, the plurality of pixels PX is configured to have an RG BG pentile disposition structure. Accordingly, the number of sub pixels included in one pixel PX and a size of one pixel PX may be smaller than those of an RGB stripe disposition in which one pixel PX is configured by red, green, and blue sub pixels. Accordingly, an interval between the bank BNK of the first sub pixel SP1 and the bank BNK of the second sub pixel SP2 and an interval between the bank BNK of the third sub pixel SP3 and the bank BNK of the fourth sub pixel SP4 may be easily increased by using an available space ensured by reducing the number and the size of the sub pixels. As a result, the plurality of micro LEDs (ED) is easily transferred to the display panel 100 by a plurality of transfer processes and an interval margin between the banks BNK is ensured to minimize or reduce a defect in the transfer process.

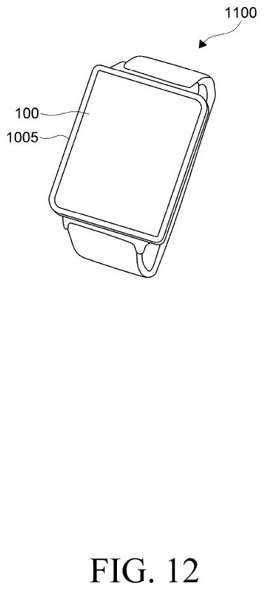

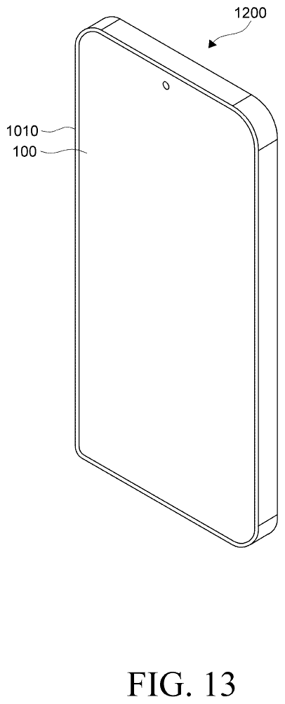

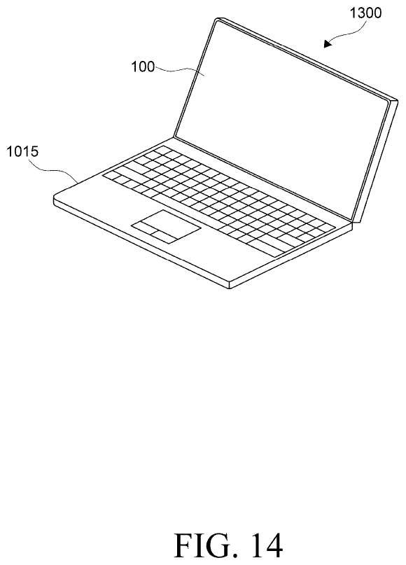

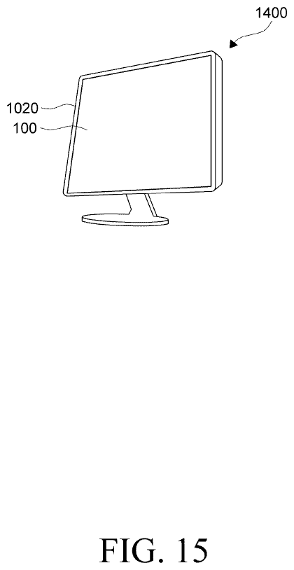

FIGS. 12 to 15 are views illustrating devices to which a display device according to exemplary embodiments of the present disclosure is applied.

Referring to FIGS. 12 to 15, the display devices 1000 according to the exemplary embodiments of the present disclosure may be included in various devices or electronic devices. For example, referring to FIGS. 12 to 15, various electronic device may include a wearable device 1100, a mobile device 1200, a notebook 1300, and a monitor or TV 1400, but the exemplary embodiments of the present disclosure are not limited thereto.

The wearable device 1100, the mobile device 1200, the notebook 1300, and a monitor or TV 1400 may include case units 1005, 1010, 1015, and 1020 and display panel 100 and the display devices 1000 according to the exemplary embodiments of the present disclosure which have been described in FIGS. 1 to 11, respectively.

For example, the display devices 1000 and 1100 according to the exemplary embodiment of the present disclosure may be applicable to a mobile device, a video phone, a smart watch, a watch phone, a wearable device, a foldable device, a rollable device, a bendable device, a flexible device, a curved device, a sliding device, a variable device, an electronic note, an electronic book, a portable multimedia player (PMP), a personal digital assistant (PDA), an MP3 player, a mobile medical device, a desktop PC, a laptop PC, a netbook computer, a workstation, a navigation, a display device for a vehicle, a theatrical display device, a television, a wallpaper device, a signage device, a game device, a notebook, a monitor, a camera, a camcorder, and a consumer electronics device.

The exemplary embodiments of the present disclosure can also be described as follows:

According to an aspect of the present disclosure, a display device includes a substrate in which a plurality of first pixels and a plurality of second pixels are defined, one or more pixel driving circuits disposed on the substrate, and a plurality of micro LEDs which is disposed in the plurality of first pixels and the plurality of second pixels and is electrically connected to the pixel driving circuit, and each of the plurality of first pixels includes one pair of first sub pixels and one pair of second sub pixels and each of the plurality of second pixels includes one pair of third sub pixels and one pair of fourth sub pixels.

The display device may further include a plurality of first electrodes which is disposed in each of the pair of first sub pixels, the pair of second sub pixels, the pair of third sub pixels, and the pair of fourth sub pixels and is electrically connected to the plurality of micro LEDs and the pixel driving circuit, and a plurality of signal lines which electrically connects the plurality of first electrodes and the pixel driving circuit, and the plurality of first electrodes and the plurality of signal lines may be configured to transmit an anode voltage output from the pixel driving circuit to the plurality of micro LEDs.

The display device may further include a plurality of contact electrodes which is electrically connected to the pixel driving circuit, and one or more second electrodes which are electrically connected to the plurality of contact electrodes, and the second electrodes and the plurality of contact electrodes may be configured to transmit a cathode voltage output from the pixel driving circuit to the plurality of micro LEDs.

The plurality of micro LEDs may include a first micro LED disposed in each of the pair of first sub pixels, a second micro LED disposed in each of the pair of second sub pixels, a third micro LED disposed in each of the pair of third sub pixels, and a fourth micro LED disposed in each of the pair of fourth sub pixels, and the first micro LED, the second micro LED, and the third micro LED may emit different color light and the fourth micro LED may emits the same color light as the second micro LED.

The plurality of first pixels may be disposed on a row different from that of the plurality of second pixels.

The pair of first sub pixels may be disposed to be adjacent to each other in a column direction, the pair of second sub pixels may be disposed to be adjacent to each other in the column direction, the pair of third sub pixels may be disposed to be adjacent to each other in the column direction, and the pair of fourth sub pixels may be disposed to be adjacent to each other in the column direction.

The pair of first sub pixels and the pair of second sub pixels may be disposed on the same row and the pair of third sub pixels and the pair of fourth sub pixels may be disposed on the same row, and the pair of first sub pixels and the pair of third sub pixels may be disposed on the same column and the pair of second sub pixels and the pair of fourth sub pixels may be disposed on the same column.

The pair of first sub pixels may be configured to emit red light, the pair of second sub pixels and the pair of fourth sub pixels may be configured to emit green light, and the pair of third sub pixels may be configured to emit blue light and the pair of first sub pixels may be disposed to be adjacent to the pair of second sub pixels and the pair of third sub pixels, respectively and the pair of third sub pixels may be disposed to be adjacent to the pair of first sub pixels and the pair of fourth sub pixels, respectively.

The display device may further include a plurality of signal lines which is electrically connected between the plurality of micro LEDs and the pixel driving circuit, and the plurality of signal lines may be connected to each of the pair of first sub pixels, the pair of second sub pixels, the pair of third sub pixels, and the pair of fourth sub pixels so as to correspond thereto one-to-one.

The display device may further include a plurality of signal lines which is electrically connected between the plurality of micro LEDs and the pixel driving circuit, and one of the plurality of signal lines may be connected to some of the pair of first sub pixels, the pair of second sub pixels, the pair of third sub pixels, and the pair of fourth sub pixels.

Each of the plurality of micro LEDs may include an anode electrode, a first semiconductor layer disposed on the anode electrode, an active layer on the first semiconductor layer, a second semiconductor layer on the active layer, and a cathode electrode on the second semiconductor layer.

The display device may further include a plurality of first electrodes which is disposed below the plurality of micro LEDs and is electrically connected to the plurality of micro LEDs and the pixel driving circuit, and a solder pattern which is disposed between the plurality of first electrodes and the anode electrodes of the plurality of micro LEDs, and the plurality of first electrodes and the anode electrodes may be electrically connected by eutectic bonding using the solder pattern.

According to another aspect of the present disclosure, a display device includes a substrate in which a plurality of first pixels and a plurality of second pixels are defined, one or more pixel driving circuits disposed on the substrate, a plurality of main micro LEDs which is disposed in the plurality of first pixels and the plurality of second pixels and is electrically connected to the pixel driving circuit, and a plurality of redundancy micro LEDs which is disposed in the plurality of first pixels and the plurality of second pixels and is electrically connected to the pixel driving circuit, and each of the plurality of first pixels includes one pair of red sub pixels and one pair of green sub pixels and each of the plurality of second pixels includes one pair of blue sub pixels and one pair of green sub pixels.

The plurality of main micro LEDs may be disposed in one of the pair of red sub pixels and one of the pair of green sub pixels of the plurality of first pixels and in one of the pair of blue sub pixels and one of the pair of green sub pixels of the plurality of second pixels, and the plurality of redundancy micro LEDs may be disposed in the other one of the pair of red sub pixels and the other one of the pair of green sub pixels of the plurality of first pixels and in the other one of the pair of blue sub pixels and the other one of the pair of green sub pixels of the plurality of second pixels.

The display device may further include a plurality of banks disposed in the plurality of first pixels and the plurality of second pixels, and one of the plurality of main micro LEDs and one of the plurality of redundancy micro LEDs may be disposed on one bank among the plurality of banks.

The display device may further include a plurality of first electrodes disposed between the plurality of banks and the plurality of main micro LEDs and between the plurality of banks and the plurality of redundancy micro LEDs, and a plurality of second electrodes disposed on the plurality of main micro LEDs and the plurality of redundancy micro LEDs, and the plurality of first electrodes may correspond to the plurality of main micro LEDs and the plurality of redundancy micro LEDs one to one and some of the plurality of main micro LEDs and some of the plurality of redundancy micro LEDs may share one of the plurality of second electrodes.

Each of the plurality of main micro LEDs and the plurality of redundancy micro LEDs may include an anode electrode, a first semiconductor layer disposed on the anode electrode, an active layer on the first semiconductor layer, a second semiconductor layer on the active layer, and a cathode electrode on the second semiconductor layer.

The display device may further include a plurality of first electrodes which is disposed below the plurality of main micro LEDs and the plurality of redundancy micro LEDs and is electrically connected to the plurality of main micro LEDs and the plurality of redundancy micro LEDs and the pixel driving circuit, and a solder pattern which is disposed between the plurality of first electrodes and the anode electrodes of the plurality of main micro LEDs and the plurality of redundancy micro LEDs, the plurality of first electrodes and the anode electrodes may be electrically connected by eutectic bonding using the solder pattern.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having thereon a plurality of first pixels and a plurality of second pixels;
one or more pixel driving circuits on the substrate; and
a plurality of micro LEDs which are disposed in the plurality of first pixels and the plurality of second pixels, and the plurality of micro LEDs are electrically connected to the pixel driving circuit,
wherein each of the plurality of first pixels includes one pair of first sub pixels and one pair of second sub pixels, and each of the plurality of second pixels includes one pair of third sub pixels and one pair of fourth sub pixels.

2. The display device according to claim 1, further comprising:
a plurality of first electrodes disposed within each of the pair of first sub pixels, the pair of second sub pixels, the pair of third sub pixels, and the pair of fourth sub pixels, the plurality of first electrodes being electrically connected to the plurality of micro LEDs and to the pixel driving circuit; and
a plurality of signal lines configured to electrically connect the plurality of first electrodes and the pixel driving circuit,
wherein the plurality of first electrodes and the plurality of signal lines are configured to transmit an anode voltage output from the pixel driving circuit to the plurality of micro LEDs.

3. The display device according to claim 1, further comprising:
a plurality of contact electrodes which are electrically connected to the pixel driving circuit; and
one or more second electrodes which are electrically connected to the plurality of contact electrodes,
wherein the second electrodes and the plurality of contact electrodes are configured to transmit a cathode voltage output from the pixel driving circuit to the plurality of micro LEDs.

4. The display device according to claim 1, wherein the plurality of micro LEDs includes:
a first micro LED disposed in each of the pair of first sub pixels;
a second micro LED disposed in each of the pair of second sub pixels;
a third micro LED disposed in each of the pair of third sub pixels; and
a fourth micro LED disposed in each of the pair of fourth sub pixels, and
wherein the first micro LED, the second micro LED, and the third micro LED emit different color light and the fourth micro LED emits the same color light as the second micro LED.

5. The display device according to claim 1, wherein the plurality of first pixels is on a row different from a row of the plurality of second pixels.

6. The display device according to claim 1, wherein the pair of first sub pixels is disposed to be adjacent to each other in a column direction, the pair of second sub pixels is disposed to be adjacent to each other in the column direction, the pair of third sub pixels is disposed to be adjacent to each other in the column direction, and the pair of fourth sub pixels is disposed to be adjacent to each other in the column direction.

7. The display device according to claim 1, wherein the pair of first sub pixels and the pair of second sub pixels are on the same row and the pair of third sub pixels and the pair of fourth sub pixels are on the same row, and the pair of first sub pixels and the pair of third sub pixels are on the same column and the pair of second sub pixels and the pair of fourth sub pixels are on the same column.

8. The display device according to claim 1, wherein the pair of first sub pixels is configured to emit red light, the pair of second sub pixels and the pair of fourth sub pixels are configured to emit green light, and the pair of third sub pixels is configured to emit blue light and the pair of first sub pixels is disposed to be adjacent to the pair of second sub pixels and the pair of third sub pixels, respectively and the pair of third sub pixels is disposed to be adjacent to the pair of first sub pixels and the pair of fourth sub pixels, respectively.

9. The display device according to claim 1, further comprising:
a plurality of signal lines which are electrically connected between the plurality of micro LEDs and the pixel driving circuit,
wherein the plurality of signal lines is connected to each of the pair of first sub pixels, the pair of second sub pixels, the pair of third sub pixels, and the pair of fourth sub pixels so as to correspond thereto one-to-one.

10. The display device according to claim 1, further comprising:
a plurality of signal lines electrically connected between the plurality of micro LEDs and the pixel driving circuit,
wherein one of the plurality of signal lines is connected to some of the pair of first sub pixels, the pair of second sub pixels, the pair of third sub pixels, and the pair of fourth sub pixels.

11. The display device according to claim 1, wherein each of the plurality of micro LEDs includes:
an anode electrode;
a first semiconductor layer on the anode electrode;
an active layer on the first semiconductor layer;
a second semiconductor layer on the active layer; and
a cathode electrode on the second semiconductor layer.

12. The display device according to claim 11, further comprising:
a plurality of first electrodes which are disposed below the plurality of micro LEDs, and plurality of first electrodes are electrically connected to the plurality of micro LEDs and the pixel driving circuit.

13. The display device according to claim 12, further comprising:
a solder pattern between the plurality of first electrodes and the anode electrodes of the plurality of micro LEDs,
wherein the plurality of first electrodes and the anode electrodes are electrically connected by eutectic bonding using the solder pattern.

14. A display device comprising:
a substrate in which a plurality of first pixels and a plurality of second pixels are defined;
one or more pixel driving circuits on the substrate;
a plurality of main micro LEDs which are disposed in the plurality of first pixels and the plurality of second pixels, and the plurality of main micro LEDs are electrically connected to the pixel driving circuit; and
a plurality of redundancy micro LEDs which are disposed in the plurality of first pixels and the plurality of second pixels, and the plurality of redundancy micro LEDs are electrically connected to the pixel driving circuit,
wherein each of the plurality of first pixels includes one pair of red sub pixels and one pair of green sub pixels and each of the plurality of second pixels includes one pair of blue sub pixels and one pair of green sub pixels.

15. The display device according to claim 14, wherein the plurality of main micro LEDs is disposed in one of the pair of red sub pixels and one of the pair of green sub pixels of the plurality of first pixels and in one of the pair of blue sub pixels and one of the pair of green sub pixels of the plurality of second pixels, and the plurality of redundancy micro LEDs is disposed in the other one of the pair of red sub pixels and the other one of the pair of green sub pixels of the plurality of first pixels and in the other one of the pair of blue sub pixels and the other one of the pair of green sub pixels of the plurality of second pixels.

16. The display device according to claim 14, further comprising:
a plurality of banks disposed in the plurality of first pixels and the plurality of second pixels,
wherein one of the plurality of main micro LEDs and one of the plurality of redundancy micro LEDs are on one bank among the plurality of banks.

17. The display device according to claim 16, further comprising:
a plurality of first electrodes between the plurality of banks and the plurality of main micro LEDs and between the plurality of banks and the plurality of redundancy micro LEDs; and
a plurality of second electrodes on the plurality of main micro LEDs and the plurality of redundancy micro LEDs,
wherein the plurality of first electrodes correspond to the plurality of main micro LEDs and the plurality of redundancy micro LEDs one to one and some of the plurality of main micro LEDs and some of the plurality of redundancy micro LEDs share one of the plurality of second electrodes.

18. The display device according to claim 14, wherein each of the plurality of main micro LEDs and the plurality of redundancy micro LEDs includes:
an anode electrode;
a first semiconductor layer on the anode electrode;
an active layer on the first semiconductor layer;
a second semiconductor layer on the active layer; and
a cathode electrode on the second semiconductor layer.

19. The display device according to claim 18, further comprising:
a plurality of first electrodes which are disposed below the plurality of main micro LEDs and the plurality of redundancy micro LEDs, and the plurality of first electrodes are electrically connected to the plurality of main micro LEDs and the plurality of redundancy micro LEDs and the pixel driving circuit.

20. The display device according to claim 19, further comprising:
a solder pattern which is disposed between the plurality of first electrodes and the anode electrodes of the plurality of main micro LEDs and the plurality of redundancy micro LEDs,
wherein the plurality of first electrodes and the anode electrodes are electrically connected by eutectic bonding using the solder pattern.
